(19) United States
(12) Patent Application Publication
(10) Pub. No.: US 2007/0161207 A1
(43) Pub. Date: Jul. 12, 2007

(54) Method for Manufacturing Semiconductor Device

(76) Inventor: Hyuk Park, Ansan-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/615,133

(22) Filed: Dec. 22, 2006

(30) Foreign Application Priority Data
Dec. 28, 2005 (KR) 10-2005-0132474

(51) Int. Cl. H01L 21/76

(52) U.S. Cl. 438/424; 257/E21.545

(57) ABSTRACT

Provided is a method for manufacturing a semiconductor device. The method includes: sequentially depositing a buried oxide layer, an insulating layer, a pad oxide layer and a pad nitride layer on a silicon substrate; etching a predetermined region of the silicon substrate using a photoresist pattern as an etch mask to form a trench; implanting an impurity ion into the trench; gap-filling the impurity ion-implanted trench with an insulating material; planarizing the insulating material filled in the gap until the pad nitride layer is exposed; and removing the pad oxide layer and the pad nitride layer.

### RELATED APPLICATION(S)

This application claims priority under 35 U.S.C. §119(e) of Korean Patent Application No. 10-2005-0132474 filed Dec. 28, 2005, which is incorporated herein by reference in its entirety.

### FIELD OF THE INVENTION

The present invention relates to a device isolation layer for a semiconductor device.

### BACKGROUND OF THE INVENTION

A silicon on insulating layer (SOI) device is a semiconductor device that uses a wafer having a structure comprised of an insulating layer and a single crystal silicon layer formed thereon. Since a thin insulating layer is buried between a substrate surface for forming a circuit and a lower layer of a substrate, the SOI device has the characteristics that a parasitic capacitance can be reduced to enhance a performance of the device.

A limited number (e.g., several thousands to several ten billions) of unit devices such as a transistor, capacitor and the like may be integrated into a semiconductor device according to a capacity of the semiconductor device. These unit devices need to be separated (or isolated) from one another for independent operation characteristics.

Methods for an electrical separation between these unit devices such as a local oxidation of silicon (LOCOS), which includes recessing a silicon substrate and growing a field oxide; and a shallow trench isolation (STI), which includes etching a silicon substrate in a perpendicular direction and filling a trench with an insulating material, are well known.

Among the above methods, the STI is a method using dry etching such as a reactive ion etching or a plasma etching to form a narrow and deep shallow trench, which is then gap-filled with an insulating layer. Since the surface of the trench is planarized to reduce an area occupied by a device isolation region, the STI method is advantageous for miniaturization.

FIGS. 1A to 1E are cross sectional views showing a process for forming a STI layer in a SOI device according to a related art.

Referring to FIG. 1A, a buried oxide layer 102, an insulating layer 104, a pad oxide layer 106 and a pad nitride layer 108 are sequentially deposited on a silicon substrate 100 doped with a conductive type (e.g., P-type) impurity.

Referring to FIG. 1B, a photoresist pattern 110 to define a device isolation region is formed on the pad nitride layer 108, and a dry etching process is performed on the pad nitride layer 108, the pad oxide layer 106 and the insulating layer 104 by a reactive ion etching (RIE) method or the like using the photoresist pattern 110 as a mask until the buried oxide 102 is exposed. This etching forms a shallow trench 112. An oxide layer may be formed on the shallow trench 112 through a wet or dry etching process.

Next, after the photoresist pattern 110 is removed, a deposition process using a chemical vapor deposition (CVD) is performed. By the deposition process, an inner part of the shallow trench 112 is completely gap-filled with an insulating material (e.g. SiO₂) to form an oxide layer 114 as shown in FIG. 1C. Herein, the deposition process is performed using the CVD method such as a plasma enhanced chemical vapor deposition (PE-CVD) or a high density plasma chemical vapor deposition (HDP-CVD). A SiO₂ layer (not shown) may be formed on the semiconductor substrate 100 where the shallow trench 112 is formed through a thermal oxidation process.

Referring to FIG. 1D, a chemical mechanical polishing (CMP) process is performed to planarize the oxide layer 114 until an upper surface of the pad nitride layer 108 is exposed.

Referring to FIG. 1E, a wet etching process is lastly performed to remove the pad nitride layer 108 and the pad oxide layer 106 in sequence such that a shallow trench isolation layer 114a remains as the device isolation layer formed.

However, a stress caused by the process of forming the shallow trench isolation layer for an SOI device according to the related art acts as a factor that decreases a performance of a transistor. Herein, the stress may include a thermal oxidation in a non-planarized region, a thermal mismatch between materials, an intrinsic stress according to a deposition process using CVD and the like, which may cause a reverse-bias junction leakage and junction capacitance to be increased due to a narrow band gap.

Referring to FIG. 2, an SiO₂ oxide grown thermally after a RIE process causes a large stress at a corner of a trench, giving a tensile stress to an oxide and a compressive stress to a silicon semiconductor substrate in the upper corner of the trench, and giving reverse stresses to those in a bottom corner of the trench. As a result, there is a problem that the compressive stress is additionally applied to and accumulated in a transistor channel to cause a malfunction of a device.

### BRIEF SUMMARY

Accordingly, embodiments of the present invention are directed to a method for manufacturing a semiconductor device that substantially obviates one or more problems due to limitations and disadvantages of the related art.

An object of embodiments of the present invention is to provide a method for manufacturing a semiconductor device that can reduce a stress caused in a lower corner of a trench through a boron doping in a process of forming a shallow trench isolation layer for an SOI device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a semiconductor device, the method including: sequentially depositing a buried oxide layer, an insulating layer, a pad oxide layer and a pad nitride layer on a silicon substrate; etching a predetermined region of the silicon substrate using a photoresist pattern as an etch mask to form a trench; implanting an impurity ion into the trench; filling a gap of the impurity ion-implanted trench with an insulating material; planarizing the insulating material filled in the gap until the pad nitride is exposed; and removing the pad oxide layer and the pad nitride layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIGS. 1A to 1E are cross sectional views showing a process for forming a device isolation layer in an SOI device according to a related art.

FIG. 2 is a cross sectional view showing that a stress comes from a bottom corner of a shallow trench of an SOI device according to the related art.

FIGS. 3A to 3F are cross sectional views illustrating a process for forming a device isolation layer in an SOI device according to an embodiment of the present invention.

FIG. 4 is a cross sectional view showing that the stress decreases at a portion indicated by a circle when boron ions are implanted into a shallow trench according to an embodiment of the present invention.

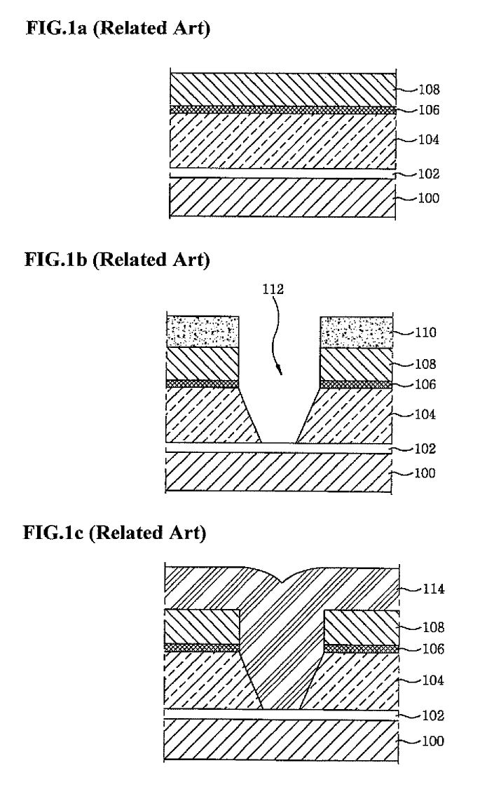

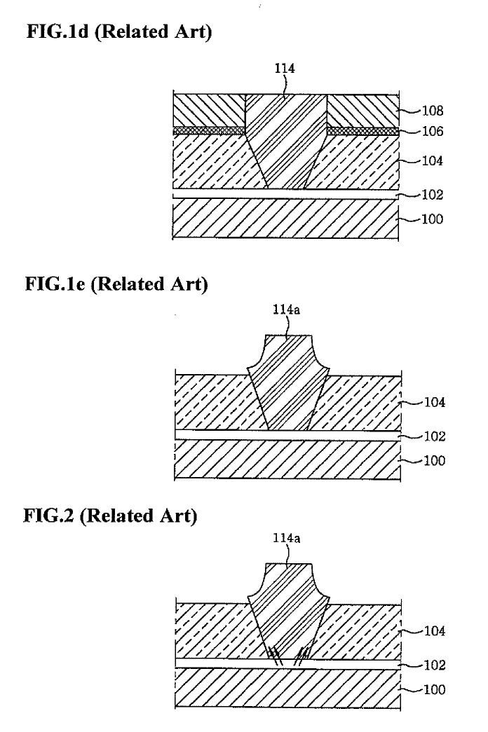

### DETAILED DESCRIPTION OF THE INVENTION

Reference will now be made in detail to the preferred embodiments of the present invention, examples of which are illustrated in the accompanying drawings.

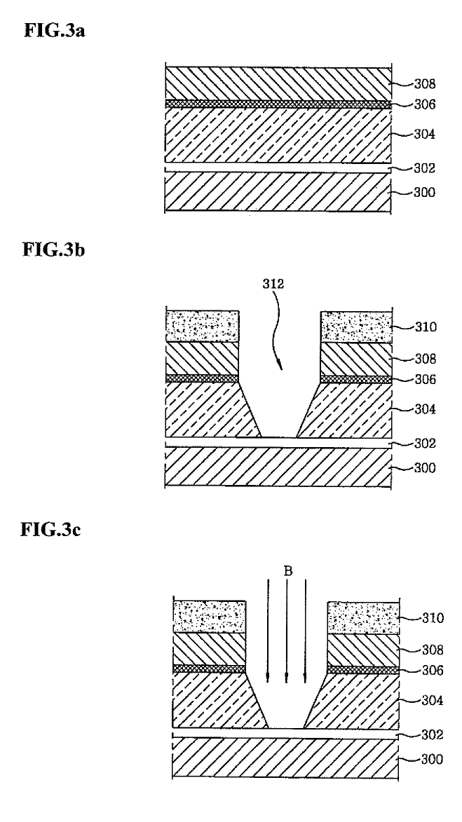

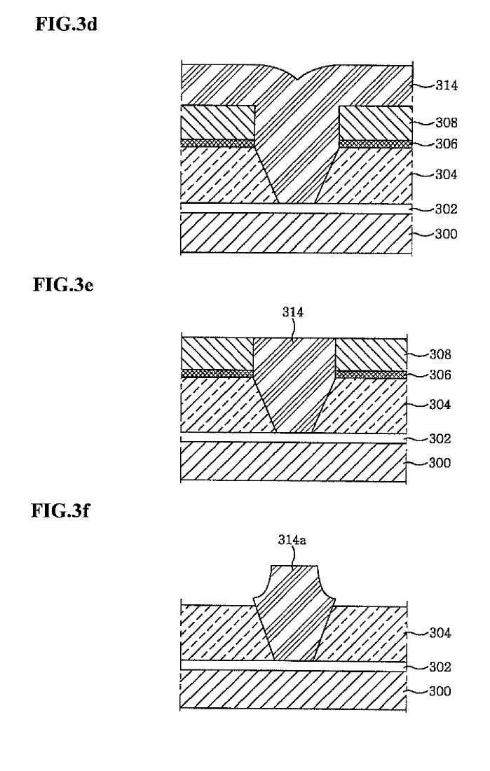

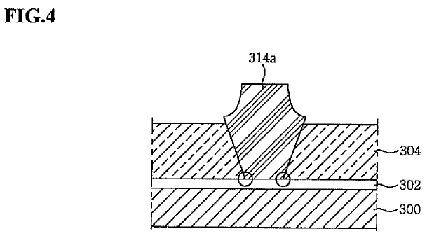

FIGS. 3A to 3F are cross sectional views illustrating a process for forming a device isolation layer in an SOI device according to an embodiment of the present invention. A method for forming a shallow trench isolation layer according to an embodiment of the present invention will be described with reference to the FIGS. 3A to 3F.

First, referring to FIG. 3A, a buried oxide layer 302, an insulating layer 304, a pad oxide layer 306 and a pad nitride layer 308 can be sequentially deposited on a silicon substrate 300 doped with a conductive type (e.g., P-type) impurity.

A photolithography and dry etching process can be performed to define a device isolation region. In one embodiment, as shown in FIG. 3B, the pad nitride layer 308, the pad oxide layer 306 and the insulating layer 304 can be etched by a reactive ion etching (RIE) method using a photoresist pattern 310 as a mask until the buried oxide layer 302 is exposed, thereby forming a shallow trench 312. In an embodiment, an oxide layer may be formed on the shallow trench 312 through a wet or dry etching process.

Referring to FIG. 3C, boron ions can be implanted into the shallow trench 312. In one embodiment, boron ions can be implanted into the shallow trench 312 using the photoresist pattern 310 as an ion implantation mask, and can be tilted approximately 10 to 20 degrees in order to be more easily implanted into a bottom corner of the shallow trench 312. The boron ions implanted into the bottom corner of the shallow trench 312 cause a local tensile stress at portions indicated by circles in the shallow trench 312 shown in FIG. 4, thus reducing a bending phenomenon of the semiconductor substrate 300 due to a compressive stress.

A dose of the impurity ions implanted into the shallow trench 312 can be 2.0E13-3.5E13 atoms/cm² and the implantation energy can be in a range of 5 KeV to 10 KeV.

In another embodiment, Germanium (Ge) may be used instead of boron as the implantation source for reducing the stress.

Next, referring to FIG. 3D, after the photoresist pattern 310 is removed, a deposition process using chemical vapor deposition (CVD) can be performed to completely gap-fill an inner part of the shallow trench 312 with an insulating material (e.g. SiO₂, USG) 314. The deposition process can be performed using a CVD method such as a plasma enhanced chemical vapor deposition (PE-CVD) or a high density plasma chemical vapor deposition (HDP-CVD). A SiO₂ oxide layer (not shown) may be formed on an upper part of the semiconductor substrate 300 where the shallow trench 312 is formed through a thermal oxidation process.

Referring to FIG. 3E, a chemical mechanical polishing (CMP) process can be performed to planarize the oxide layer 314 until an upper part of the pad nitride 308 is exposed.

Referring to FIG. 3F, a wet etching process can be performed to remove the pad nitride layer 308 and the pad oxide layer 306 in sequence such that a shallow trench isolation layer 314a remains.

Accordingly, in embodiments of the present invention, after a trench is formed for a shallow trench isolation layer in a SOI device, boron ions can be implanted into the trench, thus reducing a stress of the bottom corner of the trench.

As described above, unlike the conventional method which performs a thermal oxidation process after the shallow trench is formed in the SOI device, a method according to embodiments of the present invention includes implanting boron ions into a trench, and filling a gap of the boron-implanted trench with an insulating material. As a result, the present invention has the advantages of reducing a stress at the bottom corner of the shallow trench in a SOI device and improving the yield of the SOI device.

Furthermore, according to the present invention, boron ions implanted into the shallow trench in the ISO device may cause a local tensile stress to reduce a bending phenomenon of a substrate due to a compressive stress and suppress a additional stress accumulation arising from subsequent processes.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for manufacturing a semiconductor device, comprising:
sequentially depositing a buried oxide layer, an insulating layer, a pad oxide layer and a pad nitride layer on a silicon substrate;
etching a predetermined region of the silicon substrate using a photoresist pattern as an etch mask to form a trench;
implanting an impurity ion into the trench;
gap-filling the impurity ion-implanted trench with an insulating material;
planarizing the insulating material filled in the gap until the pad nitride layer is exposed; and
removing the pad oxide layer and the pad nitride layer.

2. The method according to claim 1, wherein the impurity ion implanted into the trench is boron (B).

3. The method according to claim 1, wherein the impurity ion implanted into the trench is germanium (Ge).

4. The method according to claim 1, wherein a dose of the impurity ion implanted into the trench is 2.0×10¹³-3.4×10¹³ atoms/cm².

5. The method according to claim 1, wherein an implantation energy of the impurity implanted into the trench is in the range of 5 KeV to 10 KeV.

6. The method according to claim 1, wherein the implantation of the impurity ion is performed tilted 10 to 20 degrees to a bottom corner of the trench.

7. The method of according to claim 1, wherein the insulating material comprises SiO₂ or USG (undoped silicate glass).
